(19) United States
(12) Patent Application Publication
(10) Pub. No.: US 2013/0247969 A1
(43) Pub. Date: Sep. 26, 2013

(54) SOLAR CELL AND METHOD OF MANUFACTURING THE SAME

(71) Applicant: Dong-Jin KIM, Yongin-si (KR)

(72) Inventor: Dong-Jin KIM, Yongin-si (KR)

(21) Appl. No.: 13/590,410

(22) Filed: Aug. 21, 2012

(30) Foreign Application Priority Data
Mar. 21, 2012 (KR) 10-2012-0028954

(51) Int. Cl. H01L 31/0224; H01L 31/18

(52) U.S. Cl. 136/256; 438/98; 257/E31.126

(57) ABSTRACT

A solar cell includes a rear electrode layer on a substrate and divided into a plurality of portions by a first separation groove, a light absorption layer and a buffer layer on the rear electrode layer and divided into a plurality of portions by a second separation groove parallel to the first separation groove, a translucent electrode layer on the buffer layer and divided into a plurality of portions by a third separation groove parallel to the first and second separation grooves, a light transmission unit exposing a portion of the substrate and defined by an opening through the rear electrode layer, the light absorption layer, the buffer layer, and the translucent electrode layer, and first and second insulation grooves at respective first and second sides of the light transmission unit, the first and second insulation grooves being perpendicular to the first through third separation grooves.

### BACKGROUND

1. Field

One or more embodiments relate to solar cells and methods of manufacturing the same, and more particularly, to a solar cell capable of preventing deterioration of a power generating efficiency by a shunt, and a method of manufacturing the solar cell.

2. Description of the Related Art

Recently, as existing energy resources, e.g., oil and coal, are expected to be exhausted, interest in alternative energies for replacing existing energy resources has risen. Among the alternative energies, solar cells are drawing attention as next generation batteries that directly change sunlight energy into electric energy by using semiconductor devices.

For example, a building-integrated photovoltaic (BIPV) system, i.e., a system using solar cells as envelop finishing materials or windows and doors of buildings, is used as an energy reduction measure and as power generating efficiency of solar cells. In the BIPV system, translucency and photoelectric conversion efficiency of solar cells are important, since the solar cells are required to perform as envelop finishing materials and power supplies via self-power generation.

### SUMMARY

One or more embodiments include solar cells capable of preventing deterioration of a power generating efficiency by a shunt, and methods of manufacturing the same.

Additional aspects will be set forth in part in the description which follows and, in part, will be apparent from the description, or may be learned by practice of the presented embodiments.

According to one or more embodiments, a solar cell includes a rear electrode layer disposed on a substrate, the rear electrode layer being divided into a plurality of portions by a first separation groove, a light absorption layer and a buffer layer disposed on the rear electrode layer, the light absorption layer and buffer layer being divided into a plurality of portions by a second separation groove parallel to the first separation groove, a translucent electrode layer disposed on the buffer layer, the translucent electrode layer being divided into a plurality of portions by a third separation groove parallel to the first and second separation grooves, a light transmission unit exposing a portion of the substrate, the light transmission unit being defined by an opening through the rear electrode layer, the light absorption layer, the buffer layer, and the translucent electrode layer, and first and second insulation grooves at respective first and second sides of the light transmission unit, the first and second insulation grooves being perpendicular to the first through third separation grooves.

The light transmission unit may be disposed between the second and third separation grooves.

A length of each of the first and second insulation grooves along a first direction may be equal to or greater than a width of the light transmission unit along the first direction.

The first and second insulation grooves may contact the third separation groove.

The first and second insulation grooves may extend from the translucent electrode layer to a top surface of the rear electrode layer.

The first and second insulation grooves and the light transmission unit may be integrally formed.

The third separation groove and the light transmission unit may be integrally formed.

The rear electrode layer may include molybdenum (Mo).

The light absorption layer may include at least one of copper (Cu), indium (In), germanium (Ge), and selenium (Se).

According to one or more embodiments, a method of manufacturing a solar cell includes forming a rear electrode layer on a substrate, and forming a first separation groove dividing the rear electrode layer by performing a first patterning; forming a light absorption layer and a buffer layer on the rear electrode layer, forming a second separation groove dividing the light absorption layer and buffer layer by performing a second patterning, forming a translucent electrode layer on the buffer layer, and forming a third separation groove defining a plurality of photoelectric units by performing a third patterning, forming a light transmission unit by removing parts of the rear electrode layer, the light absorption layer, buffer layer, and the translucent electrode layer, and forming a pair of insulation grooves respectively at two sides of the light transmission unit, wherein the pair of insulation grooves are formed perpendicular to the first through third separation grooves that are parallel to each other.

The light transmission unit may be formed between the second and third separation grooves.

The first and second insulation grooves may be formed to contact the third separation groove.

The first and second insulation grooves and the third separation groove may be formed by removing parts of the translucent electrode layer, buffer layer, and light absorption layer.

The first and second insulation grooves and the light transmission unit may be integrally formed.

The light transmission unit and the third separation groove may be integrally formed.

### BRIEF DESCRIPTION OF THE DRAWINGS

Features will become apparent to those of ordinary skill in the art by describing in detail exemplary embodiments with reference to the attached drawings, in which:

FIG. 1 illustrates a plan view of a solar cell according to an embodiment;

FIG. 2 illustrates a cross-sectional view taken along line I-I′ of FIG. 1;

FIG. 3 illustrates a cross-sectional view taken along line II-II′ of FIG. 1;

FIG. 4 illustrates a plan view of a solar cell according to another embodiment;

FIG. 5 illustrates a magnified view of a region A of FIG. 4;

FIG. 6 illustrates a plan view of a solar cell according to another embodiment;

FIG. 7 illustrates a cross-sectional view taken along line of FIG. 6;

FIG. 8 illustrates a cross-sectional view taken along line IV-IV′ of FIG. 6;

FIG. 9 illustrates a magnified view of a region B of FIG. 6; and

FIGS. 10 through 13 illustrate cross-sectional views of stages in a method of manufacturing a solar cell according to an embodiment.

### DETAILED DESCRIPTION

Korean Patent Application No. 10-2012-0028954, filed on Mar. 21, 2012, in the Korean Intellectual Property Office, and entitled: “Solar Cell and Method of Manufacturing the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer, i.e., an element, is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

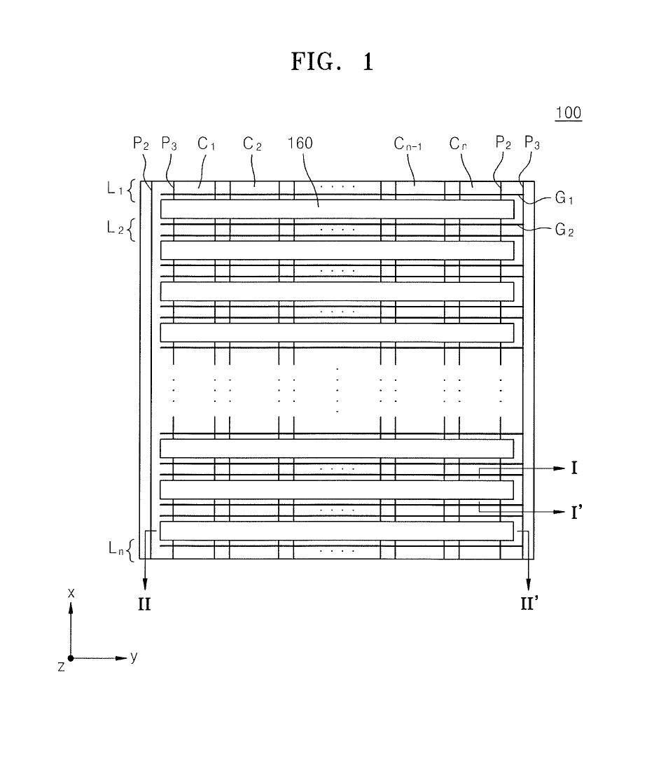

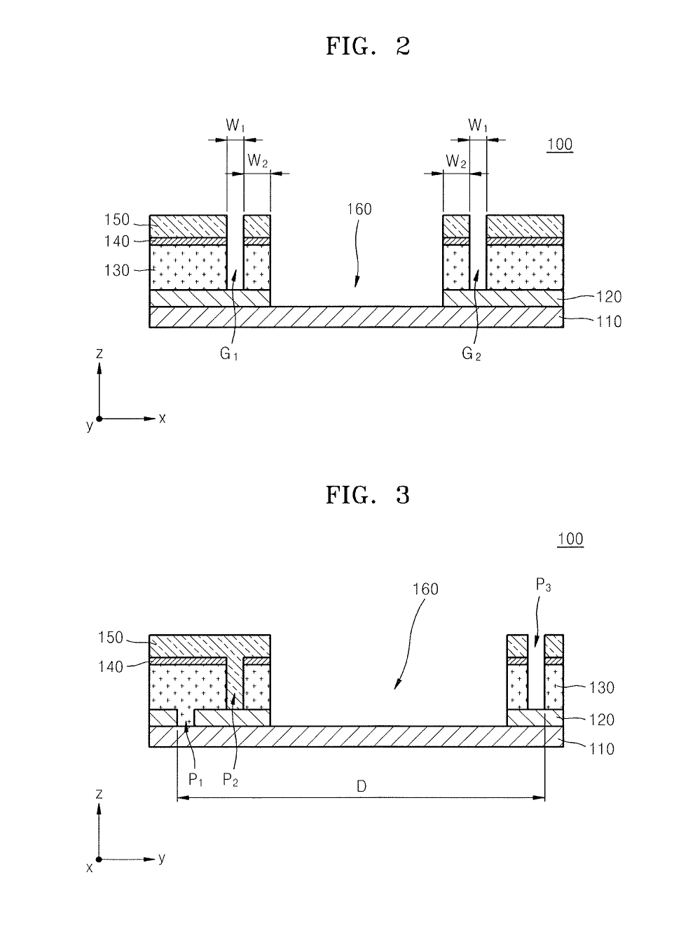

FIG. 1 is a plan view of a solar cell 100 according to an embodiment, FIG. 2 is a cross-sectional view taken along line I-I′ of FIG. 1, and FIG. 3 is a cross-sectional view taken along line II-II′ of FIG. 1. Here, FIG. 1 illustrates the solar cell 100 on an x-y plane viewed from a z-direction, FIG. 2 illustrates the solar cell 100 on an x-z plane viewed from a y-direction, and FIG. 3 illustrates the solar cell 100 on a y-z plane viewed from an x-direction.

Referring to FIGS. 1 through 3, the solar cell 100 according to the current embodiment may include a substrate 110, a rear electrode layer 120 disposed on the substrate 110 and divided by a first separation groove P1, a light absorption layer 130 and a buffer layer 140 disposed on the rear electrode layer 120 and divided by a second separation groove P2, a translucent electrode layer 150 disposed on the buffer layer 140 and divided by a third separation groove P3, and a light transmission unit 160 formed by removing parts of the rear electrode layer 120, the light absorption layer 130, buffer layer 140, and the translucent electrode layer 150. Also, the solar cell 100 may further include a pair of insulation grooves G1 and G2 respectively at two sides of the light transmission unit 160.

The substrate 110 may be, e.g., a glass substrate having excellent light translucency or a polymer substrate. For example, the glass substrate may be formed of soda-lime glass or high strained point soda glass, and the polymer substrate may be formed of polyimide, but are not limited thereto. In another example, the glass substrate may be formed of low iron tempered glass protecting internal devices from external shock and containing a low amount iron to increase a transmittance of sunlight. Examples of low iron tempered glass may include soda-lime glass with low amount of iron, where sodium (Na) ions are extracted from the glass at a process temperature higher than 500° C. to increase efficiency of the light absorption layer 130 formed of Copper-Indium-Gallium-Selenide (CIGS).

The rear electrode layer 120 may be formed of a metal exhibiting excellent conductivity and excellent light reflectivity, e.g., molybdenum (Mo), aluminum (Al), and/or copper (Cu), such that charges formed by a photoelectric effect are collected and re-absorbed by the light absorption layer 130 by reflecting light that penetrates through the light absorption layer 130. For example, the rear electrode layer 120 may include Mo to provide high conductivity, an ohmic-contact with the light absorption layer 130, and high temperature stability under a selenium (Se) atmosphere.

The rear electrode layer 120 may have a thickness from about 200 nm to about 500 nm along the z-axis, and may be divided into a plurality of portions by the first separation groove P1. The first separation groove P1 may be a groove parallel to one direction of the substrate 110, e.g., along the x-axis. For example, the first separation groove P1 may extend through the entire thickness of the rear electrode layer 120 along the z-axis to expose a portion of the substrate 110.

The rear electrode layer 120 may be doped with alkali ions, e.g., Na ions. For example, while growing the light absorption layer 130 formed of CIGS on the rear electrode layer 120, the alkali ions doped in the rear electrode layer 120 are mixed with the light absorption layer 130, thereby having a structurally favorable effect on the light absorption layer 130 and improving conductivity of the light absorption layer 130. Accordingly, a stand-off ratio Voc of the solar cell 100 is increased, and thus, an efficiency of the solar cell 100 may be improved.

Also, the rear electrode layer 120 may be formed of multiple films along the z-axis so as to obtain resistance characteristics of a contact surface with the substrate 110 and the rear electrode layer 120.

The light absorption layer 130 is formed of a CIGS-based compound, e.g., the light absorption layer 130 may consist essentially of CIGS, to form a P-type semiconductor layer and to absorb incident sunlight. The light absorption layer 130 may be formed on the rear electrode layer 120 and in the first separation groove P1 separating the rear electrode layer 120, i.e., the light absorption layer 130 may contact the substrate 110 through the first separation groove P1. The light absorption layer 130 may have a thickness from about 0.7 μm to about 2 μm.

The buffer layer 140 may be formed on the light absorption layer 130 and may reduce a band gap difference between the light absorption layer 130 and the translucent electrode layer 150 to be described below. Further, the buffer layer 140 reduces recombination of holes and electrons that may be generated between the light absorption layer 130 and the translucent electrode layer 150. The buffer layer 140 may be formed of, e.g., cadmium sulfide (CdS), zinc sulfide (ZnS), indium sulfide (In₂S₃), and/or zinc magnesium oxide (ZnₓMg(₁₋ₓ)O).

The light absorption layer 130 and the buffer layer 140 may be divided into a plurality of portions by the second separation groove P2. The second separation groove P2 may be a groove parallel to the first separation groove P1 at a different location from the first separation groove P1. The second separation groove P2 may extend thorough an entire combined thickness of the light absorption layer 130 and the buffer layer 140 along the z-axis to expose a top surface of the rear electrode layer 120.

The translucent electrode layer 150 may be formed on the buffer layer 140, so the translucent electrode layer 150 and the light absorption layer 130 form a P-N junction. Also, the translucent electrode layer 150 is formed of a transparent conductive material, e.g., boron-doped zinc oxide (ZnO:B), indium tin oxide (ITO), or indium zinc oxide (IZO), so as to capture charges formed by a photoelectric effect. Also, although not shown in FIGS. 1 through 3, a top surface of the translucent electrode layer 150 may be textured so as to reduce reflection of incident sunlight and increase light absorption by the light absorption layer 130.

The translucent electrode layer 150 may be formed in the second separation groove P2 to contact the rear electrode layer 120 exposed by the second separation groove P2. Therefore, the translucent electrode layer 150 may electrically connect the light absorption layer 130, i.e., the plurality of portions of the light absorption layer 130, by the second separation groove P2. In other words, two adjacent portions of the light absorption layer 130 along the y-axis may be on, e.g., directly on, a same portion of the rear electrode layer 120. The translucent electrode layer 150 may contact the same portion of the rear electrode layer 120 through the second separation groove P2, i.e., between the two adjacent portions of the light absorption layer 130.

The translucent electrode layer 150 may be divided into a plurality of portions by the third separation groove P3 formed at a different location from the first and second separation grooves P1 and P2. The third separation groove P3 may be a groove parallel to the first and second separation grooves P1 and P2, and may extend to a top surface of the rear electrode layer 120, thereby forming a plurality of first through nth photoelectric units C1 through Cn.

An insulation material, e.g., air, may be charged in the third separation groove P3 so as to form an insulation layer between the first through nth photoelectric units C1 through Cn. Thus, the first through nth photoelectric units C1 through Cn may be connected in series in a transverse direction of FIG. 1, e.g., along the y-axis, perpendicular to the third separation groove P3, e.g., along the x-axis.

The light transmission unit 160 may be formed at a location where the parts of the rear electrode layer 120, the light absorption layer 130, the buffer layer 140, and the translucent electrode layer 150 are removed. In other words, as illustrated in FIGS. 2-3, a portion of the rear electrode layer 120, the light absorption layer 130, the buffer layer 140, and the translucent electrode layer 150 may be removed to define an opening, i.e., the light transmission unit 160, exposing a top surface of the substrate 110.

In FIG. 1, the light transmission unit 160 is formed in the transverse direction, e.g., along the y-axis. For example, each light transmission unit 160 may extend continuously along the y-axis to transverse the first through nth photoelectric units C1 through Cn, and a plurality of light transmission units 160 may be spaced apart from each other along the x-axis. In this case, the first through nth photoelectric units C1 through Cn connected in series in the transverse direction may form a plurality of arrays L1 through Ln in a longitudinal direction, e.g., along the x-axis, and the arrays L1 through Ln may be connected in parallel.

As shown in FIG. 2, the pair of insulation grooves G1 and G2 may be formed respectively on two sides of the light transmission unit 160. In other words, the light transmission unit 160 may be positioned between the insulation grooves G1 and G2 in the x-axis direction. The insulation grooves G1 and G2 are perpendicular to the first through third separation grooves P1 through P3, which are parallel to each other, and extend to the top surface of the rear electrode layer 120. For example, the first through third separation grooves P1 through P3 may extend along the x-axis, while the insulation grooves G1 and G2 may extend along the y-axis and may expose the top surface of the rear electrode layer 120.

Accordingly, the first through nth photoelectric units C1 through Cn connected in series may be electrically separated from an inner surface of the light transmission unit 160 in the x-direction of FIG. 1. For example, as illustrated in FIG. 1, the first through nth photoelectric units C1 through Cn in the first array L1 may be separated from the first light transmission unit 160 along the x-axis by the insulation groove G1. Similarly, the first through nth photoelectric units C1 through Cn in the second array L2 may be separated from the first and second light transmission unit 160 along the x-axis by the respective insulation grooves G1 and G2. As such, the first through nth photoelectric units C1 through Cn are separated from potential conductive residue in the light transmission unit 160, thereby improving efficiency of the solar cell 100.

In detail, as the light transmission unit 160 may be formed via a laser scribing process, conductive material of the translucent electrode layer 150 evaporated by a laser beam during the laser scribing process may be re-deposited inside of the light transmission unit 160. The re-deposited conductive material inside the light transmission unit 160 may potentially form a shunt path, thereby decreasing efficiency of the solar cell 100. However, as according to example embodiments, the first through nth photoelectric units C1 through Cn are separated from the light transmission unit 160, i.e., where the shunt path may be generated, by insulating grooves, efficiency of the solar cell 100 may not be affected, i.e., efficiency may be prevented from decreasing due to the shunt path.

As shown in FIG. 3, the light transmission unit 160 may be disposed between the second and third separation grooves P2 and P3. Here, the second and third separation grooves P2 and P3 do not only denote the second and third separation grooves P2 and P3 adjacent to each other, but may denote the second and third separation grooves P2 and P3 disposed in the first through nth photoelectric units C1 through Cn. However, based on FIG. 1 where the first through third separation grooves P1 through P3 are formed while moving in the y-direction, when the light transmission unit 160 is formed between the second and third separation grooves P2 and P3, the third separation groove P3 may be on the right, i.e., in the y-direction, with respect to the second separation groove P2.

As such, when the light transmission unit 160 is disposed between the second and third separation grooves P2 and P3, the light transmission unit 160 is disposed inside a non-power generation region D. Accordingly, even if a conductive material is re-deposited in the light transmission unit 160 disposed in the y-direction of FIG. 1 while performing the laser scribing process to form the light transmission unit 160, the solar cell 100 is not affected by the shunt path.

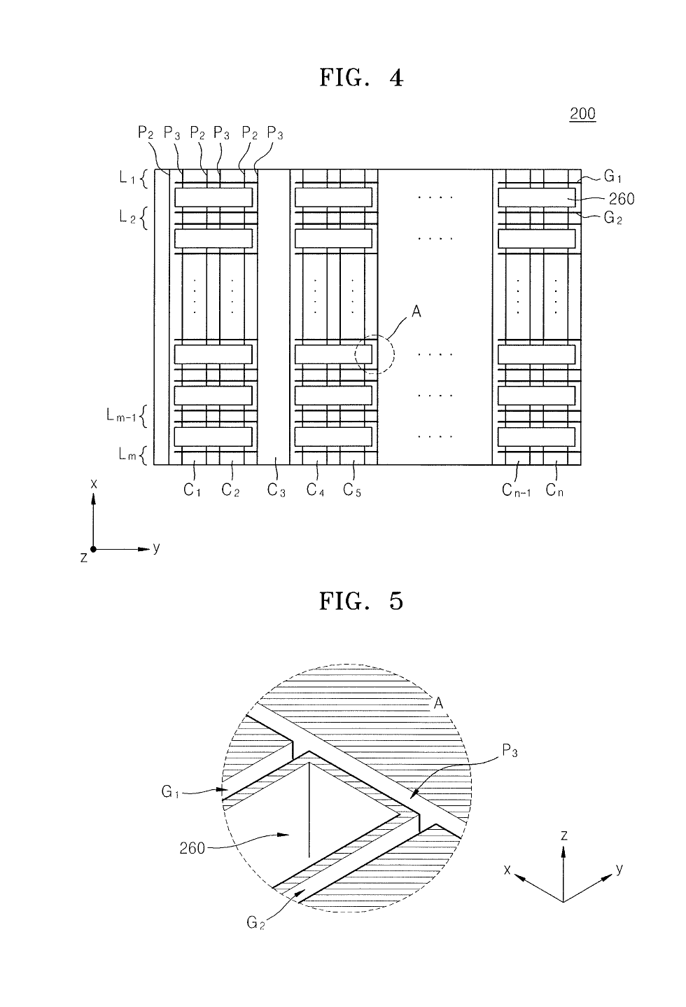

Lengths of the insulation grooves G1 and G2 along the y-axis may be equal to or greater than a width of the light transmission unit 160 along the y-axis. The insulation grooves G1 and G2 may contact the third separation groove P3, as will be described below with reference to FIGS. 4 and 5.

Referring back to FIG. 2, a width W1 of the insulation grooves G1 and G2 along the x-axis may be from about 30 μm to about 90 μm considering a decrease in a power generation region of the solar cell 100. A distance W2 between the insulation grooves G1 and G2 and the light transmission unit 160 along the x-axis may be from about 10 μm to about 30 μm, but are not limited thereto. For example, as described below, the insulation grooves G1 and G2 and the light transmission unit 160 may be continuously formed, i.e., the distance W2 may be 0.

FIG. 4 is a plan view of a solar cell 200 according to another embodiment. FIG. 5 is a magnified view of a region A of FIG. 4.

FIG. 4 shows a light transmission unit 260 formed throughout every two photoelectric units. In other words, adjacent light transmission units 260 along the y-axis may be separated from each other. For example, first and second photoelectric units C1 and C2 where the light transmission unit 260 is formed are connected in series in a transverse direction, and form a plurality of arrays L1 through Lm connected in parallel in a longitudinal direction. Similarly, fourth and fifth photoelectric units C4 and C5 or n−1th and nth photoelectric units Cn−1 and Cn form a plurality of arrays connected in parallel in the longitudinal direction. Accordingly, based on a location of the light transmission unit 260, the first through nth photoelectric units C1 through Cn may be connected in series, parallel, or both in series and parallel.

As described above with reference to FIGS. 1 through 3, the solar cell 200 of FIG. 4 may also include a pair of insulation grooves G1 and G2 respectively at two sides of the light transmission unit 260, so as to prevent an efficiency decrease of the solar cell 200 due to a shunt path that may be generated inside of the light transmission unit 260. Here, lengths of the insulation grooves G1 and G2 may be equal to or greater than a width of the light transmission unit 260 parallel to a length direction of the insulation grooves G1 and G2, thereby decreasing an effect of the shunt path that may be generated within the light transmission unit 260.

Also, as shown in FIG. 4, the light transmission unit 260 may overlap a plurality of second and third separation grooves P2 and P3, and may be disposed between the pair of insulation grooves G1 and G2. For example, as further illustrated in FIG. 4, two third separation grooves P3 and one second separation groove P2 may define each photoelectric unit. As shown in FIG. 5, the pair of insulation grooves G1 and G2 may connect with the third separation groove P3.

For example, when the light transmission unit 260 is formed throughout the fourth and fifth photoelectric cells C4 and C5, the pair of insulation grooves G1 and G2 formed respectively on two sides of the light transmission unit 260 cross the two third separation grooves P3 defining the fourth photoelectric cell C4, and thus, the fourth photoelectric cell C4 is not affected by a shunt formed inside of the light transmission unit 260.

One third separation groove P3 from among the two third separation grooves P3 defining the fifth photoelectric cell C5 is the same third separation groove P3 when the light transmission unit 260 is disposed between the second and third separation grooves P2 and P3. Therefore, the inside of the light transmission unit 260 and a power generation region of the solar cell 200 are definitely separated from each other by forming the insulation grooves G1 and G2 to contact the third separation groove P3 in the y-direction from among the two third separation grooves P3 defining the fifth photoelectric cell C5, as shown in FIG. 5.

However, when the light transmission unit 260 is disposed between the second and third separation grooves P2 and P3, the insulation grooves G1 and G2 respectively at two sides of the light transmission unit 260 may not contact the second separation groove P2. This is because, since a region between the second and third separation grooves P2 and P3 is a non-power generation region and the second separation groove P2 electrically connects the translucent electrode layer 150 and the rear electrode layer 120, a power generating efficiency of the solar cell 200 is not affected even if a shunt is generated inside of the light transmission unit 260 near the second separation groove P2.

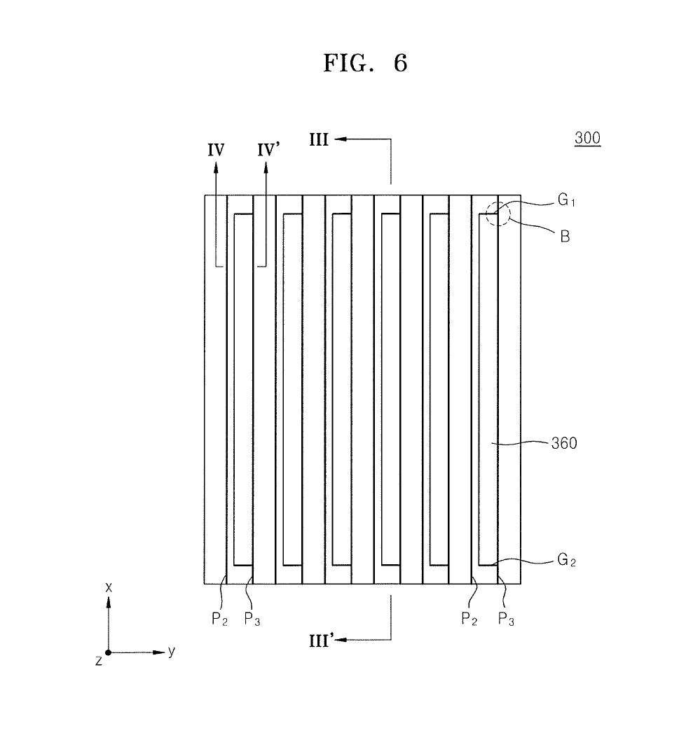

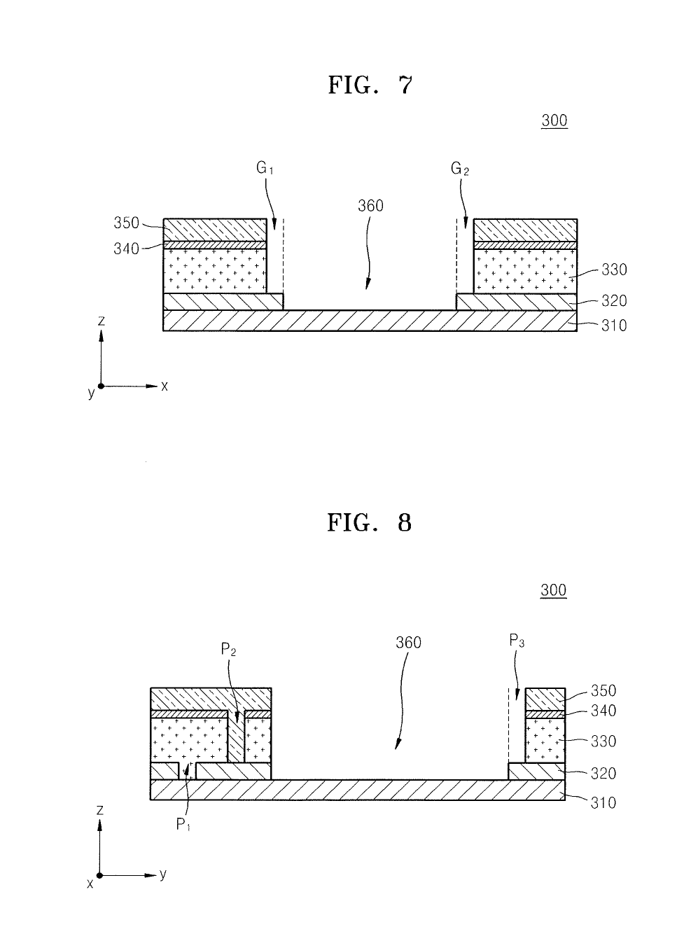

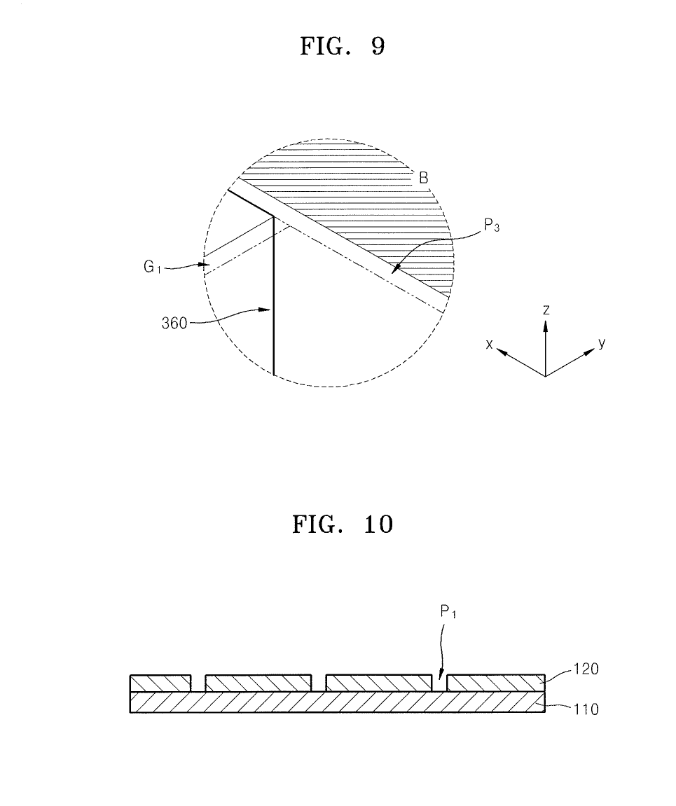

FIG. 6 is a plan view of a solar cell 300 according to another embodiment. FIG. 7 is a cross-sectional view taken along line of FIG. 6, FIG. 8 is a cross-sectional view taken along line IV-IV′ of FIG. 6, and FIG. 9 is a magnified view of a region B of FIG. 6.

First, referring to FIGS. 6 through 8, the solar cell 300 according to the current embodiment may include a substrate 310, a rear electrode layer 320 divided by a first separation groove P1, a light absorption layer 330 and a buffer layer 340 divided by a second separation groove P2, a translucent electrode layer 350 divided by a third separation groove P3, and a light transmission unit 360. The light transmission unit 360 may include a pair of insulation grooves G1 and G2 respectively at two sides of the light transmission unit 360. Also, the light transmission unit 360 may be disposed between the second and third separation grooves P2 and P3 along the y-axis, and the insulation grooves G1 and G2 may contact the third separation groove P3.

Since the substrate 310, the rear electrode layer 320, the light absorption layer 330, the buffer layer 340, the translucent electrode layer 350, and the light transmission unit 360 are respectively identical to the substrate 110, the rear electrode layer 120, the light absorption layer 130, the buffer layer 140, the translucent electrode layer 150, and the light transmission unit 160, repeated descriptions thereof are not provided.

In the solar cell 300 of FIG. 6, each first through nth photoelectric unit C1 through Cn includes the light transmission unit 360 formed in a longitudinal direction. Also, in FIG. 7, the pair of insulation grooves G1 and G2 and the light transmission unit 360 may be integrally formed, e.g., formed as a single opening where the insulation grooves G1 and G2 and light transmission unit 360 are in fluid communication, and in FIG. 8, the third separation groove P3 and the light transmission unit 360 may be integrally formed.

As such, when the light transmission unit 360 contacts the pair of insulation grooves G1 and G2 and/or the third separation groove P3, an efficiency of the solar cell 300 may be increased as a non-power generation region in the solar cell 300 is decreased, as shown in FIG. 9.

FIGS. 10 through 13 are cross-sectional views of stages in a method of manufacturing a solar cell according to an embodiment. The method of FIGS. 10 through 13 is one of manufacturing the solar cell 100 of FIGS. 1 through 3, but the method may also be applied to the solar cells 200 and 300 of FIGS. 4 through 9.

Referring to FIG. 10, the rear electrode layer 120 may be formed on the substrate 110. Then, the rear electrode layer 120 may be divided into a plurality of portions by performing a first patterning, as shown in FIG. 10.

For example, the rear electrode layer 120 may be formed by coating a conductive paste on the substrate 110 and then performing a thermal process. In another example, the rear electrode layer 120 may be formed by a plating process. In yet another example, the rear electrode layer 120 may be formed via a sputtering process, e.g., using a Mo target.

The first patterning may be performed via a laser scribing process to form the first separation groove P1. The laser scribing process is a process of evaporating some of the rear electrode layer 120 by irradiating a laser beam towards the substrate 110 from a bottom of the substrate 110. The first separation groove P1 divides the rear electrode layer 120 at regular intervals, e.g., the rear electrode layer 120 may be divided into a plurality of discrete portions spaced apart from each other at a constant interval.

Next, as shown in FIG. 11, the light absorption layer 130 and the buffer layer 140 may be formed, followed by a second patterning is performed.

For example, the light absorption layer 130 may be formed by using a co-evaporation method wherein Cu, In, Ga, and Se are put into a small electric furnace installed in a vacuum chamber, and are heated for vacuum deposition. In another example, the light absorption layer 130 may be formed by a sputtering/selenization method, where a CIG-based metal precursor film is formed on the rear electrode layer 120 by using a Cu target, an In target, and a Ga target, and then the CIG-based metal precursor film is thermally treated under a hydrogen selenide (H₂Se) gas atmosphere, such that the CIG-based metal precursor film reacts with Se to form a CIGS-based light absorption layer. In another example, the light absorption layer 130 may be formed by using an electro-deposition method or a molecular organic chemical vapor deposition (MOCVD) method.

The buffer layer 140 reduces a band gap difference between the light absorption layer 130 of a P-type and the translucent electrode layer 150 of an N-type, and reduces re-combination of electrons and holes that may be generated on an interface between the light absorption layer 130 and the translucent electrode layer 150. The buffer layer 140 may be formed via, e.g., a chemical bath deposition (CBD) method, an atomic layer deposition (ALD) method, or an ion lay gas reaction (ILGAR) method.

After forming the light absorption layer 130 and the buffer layer 140, the second patterning is performed. For example, the second patterning may be performed via mechanical scribing, where the second separation groove P2 may be formed by moving a sharp object, e.g., a needle, in a direction parallel to the first separation groove P1 to a location spaced apart from the first separation groove P1. In another example, the second patterning may be performed by using a laser beam.

The second patterning divides the light absorption layer 130 into a plurality of portions, and the second separation groove P2 formed via the second patterning extends to a top surface of the rear electrode layer 120 to expose the rear electrode layer 120.

Next, as shown in FIG. 12, after forming the translucent electrode layer 150, a third patterning is performed.

The translucent electrode layer 150 may be formed of a transparent conductive material, e.g., ZnO:B, ITO, or IZO, by using an MOCVD method, a low-pressure chemical vapor deposition (LPCVD) method, or a sputtering method. The translucent electrode layer 150 is also formed in the second separation groove P2, thereby electrically connecting the light absorption layers 130 divided by the second separation groove P2.

The third patterning may be performed via a mechanical scribing method, and the third separation groove P3 formed via the third patterning may extend to a top surface of the rear electrode layer 120 to form a plurality of photoelectric units. Also, an insulation layer may be formed by charging air in the third separation groove P3.

Although not shown in FIG. 12, a top surface of the translucent electrode layer 150 may be textured. Here, texturing denotes forming a ribbed pattern on a surface via a physical or chemical method. As such, when the top surface of the translucent electrode layer 150 is rough via texturing, reflectivity of an incident light is reduced, and thus, an amount of captured light may be increased. Accordingly, optical loss may be reduced.

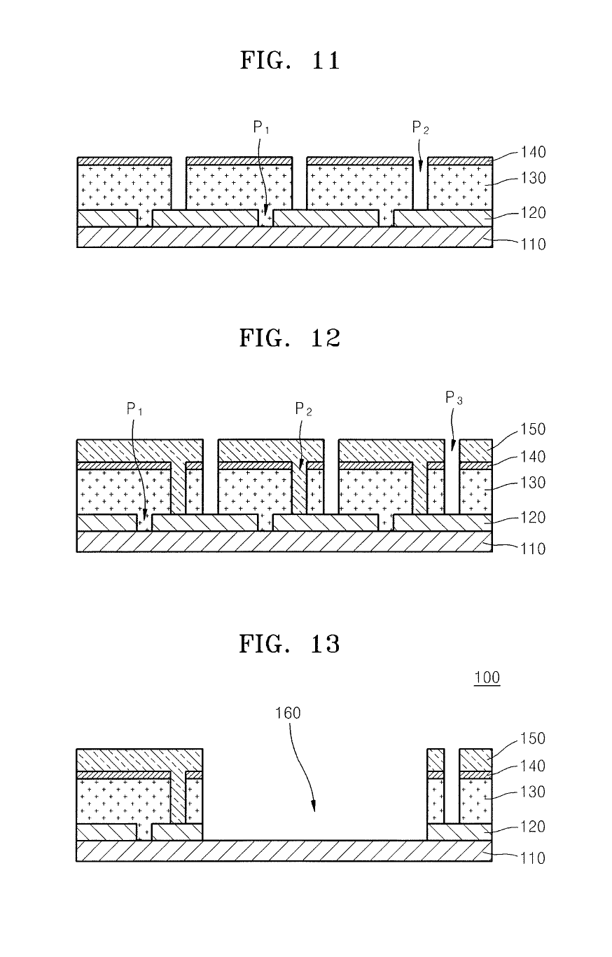

Next, as shown in FIG. 13, parts of the rear electrode layer 120, the light absorption layer 130, the buffer layer 140, and the translucent electrode layer 150 are removed to form the light transmission unit 160. Also, after forming the light transmission unit 160, the pair of insulation grooves G1 and G2 are respectively formed at two sides of the light transmission unit 160, as shown in FIGS. 1 and 2.

The parts of the rear electrode layer 120, the light absorption layer 130, the buffer layer 140, and the translucent electrode layer 150 may be removed via a laser scribing method using a laser having a wavelength from about 1060 nm to about 1064 nm, a pulse width from about 10 ns to about 100 nm, and power from about 0.5 W to about 20 W, but is not limited thereto. Here, the light transmission unit 160 may be formed between the second and third separation grooves P2 and P3. Furthermore, as shown in FIG. 8, the light transmission unit 160 may contact the third separation groove P3.

The insulation grooves G1 and G2 of FIG. 2 may be formed to expose the top surface of the rear electrode layer 120 via a mechanical scribing method. Accordingly, an efficiency of the solar cell 100 may be prevented from being deteriorated by a shunt path that may be generated while forming the light transmission unit 160. Further, as shown in FIG. 7, the insulation grooves G1 and G2 may contact the light transmission unit 360, thereby reducing a non-power generation region.

As described above, according to the one or more of the above embodiments, deterioration of a power generating efficiency of a solar cell, e.g., due to a shunt generated while forming a light transmission unit, may be prevented. Also, the light transmission unit may be formed to contact a pair of insulation grooves and/or a third separation groove, thereby reducing a non-power generation region of the solar cell.

In contrast, in a conventional solar cell, e.g., used in the BIPV system, a light transmission unit is formed by performing a laser scribing process. However, as described previously, the laser scribing process may cause a conductive material (for example, a transparent conducting oxide (TCO)-based translucent electrode layer) may be re-deposited at a side, e.g., an inner surface, of the light transmission unit, thereby forming a shunt resistance path, i.e., an unnecessary current path. Such a shunt in the conventional solar cell may reduce the power generating efficiency of the solar cell.

The solar cells according to one or more embodiments are not limited to the structures and methods described above, and all or some of the embodiments may be selectively combined for various modifications.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the embodiments as set forth in the following claims.

What is claimed is:

1. A solar cell, comprising:
a rear electrode layer disposed on a substrate, the rear electrode layer being divided into a plurality of portions by a first separation groove;
a light absorption layer and a buffer layer disposed on the rear electrode layer, the light absorption layer and buffer layer being divided into a plurality of portions by a second separation groove parallel to the first separation groove;
a translucent electrode layer disposed on the buffer layer, the translucent electrode layer being divided into a plurality of portions by a third separation groove parallel to the first and second separation grooves;
a light transmission unit exposing a portion of the substrate, the light transmission unit being defined by an opening through the rear electrode layer, the light absorption layer, the buffer layer, and the translucent electrode layer; and
first and second insulation grooves at respective first and second sides of the light transmission unit, the first and second insulation grooves being perpendicular to the first through third separation grooves.

2. The solar cell as claimed in claim 1, wherein the light transmission unit is disposed between the second and third separation grooves.

3. The solar cell as claimed in claim 2, wherein the first and second insulation grooves contact the third separation groove.

4. The solar cell as claimed in claim 2, wherein the third separation groove and the light transmission unit are integral with each other.

5. The solar cell as claimed in claim 1, wherein a length of each of the first and second insulation grooves along a first direction is equal to or greater than a width of the light transmission unit along the first direction.

6. The solar cell as claimed in claim 1, wherein the first and second insulation grooves extend from the translucent electrode layer to a top surface of the rear electrode layer.

7. The solar cell as claimed in claim 1, wherein the first and second insulation grooves and the light transmission unit are integral with each other.

8. The solar cell as claimed in claim 1, wherein the rear electrode layer includes molybdenum (Mo).

9. The solar cell as claimed in claim 1, wherein the light absorption layer includes copper (Cu), indium (In), germanium (Ge), and selenium (Se).

10. A method of manufacturing a solar cell, the method comprising:
forming a rear electrode layer on a substrate;
forming a first separation groove in the rear electrode by performing a first patterning to divide the rear electrode layer into a plurality of portions;
forming a light absorption layer and a buffer layer on the rear electrode layer;
forming a second separation groove by performing a second patterning to divide the light absorption layer and buffer layer into a plurality of portions;
forming a translucent electrode layer on the buffer layer;
forming a third separation groove by performing a third patterning to define a plurality of photoelectric units;
forming a light transmission unit exposing a portion of the substrate, the light transmission unit being defined by an opening through the rear electrode layer, the light absorption layer, the buffer layer, and the translucent electrode layer; and
forming first and second insulation grooves at respective first and second sides of the light transmission unit, the first and second insulation grooves being formed perpendicularly to the first through third separation grooves that are parallel to each other.

11. The method as claimed in claim 10, wherein the light transmission unit is formed between the second and third separation grooves.

12. The method as claimed in claim 11, wherein the first and second insulation grooves are formed to contact the third separation groove.

13. The method as claimed in claim 10, wherein the first and second insulation grooves and the third separation groove are formed by removing parts of the translucent electrode layer, the buffer layer, and the light absorption layer.

14. The method as claimed in claim 10, wherein the first and second insulation grooves and the light transmission unit are integrally formed.

15. The method as claimed in claim 10, wherein the light transmission unit and the third separation groove are integrally formed.
